(19) United States
(12) Patent Application Publication
(10) Pub. No.: US 2008/0041308 A1
(43) Pub. Date: Feb. 21, 2008

(54) SUBSTRATE TREATMENT APPARATUS AND CLEANING METHOD

(75) Inventors: Hyung-Sik HONG, Suwon-si (KR); Ki-Sun KIM, Yangcheon-gu (KR); No-Hyun HUH, Yongin-si (KR); Jong-Myeong LEE, Seongnam-si (KR)

Correspondence Address: VOLENTINE & WHITT PLLC, ONE FREEDOM SQUARE, 11951 FREEDOM DRIVE SUITE 1260, RESTON, VA, 20190, US

(73) Assignee: SAMSUNG ELECTRONICS CO., LTD., Gyeonggi-do (KR)

(21) Appl. No.: 11/830,156

(22) Filed: Jul. 30, 2007

(30) Foreign Application Priority Data
Aug. 18, 2006 (KR) 10-2006-0078371

(51) Int. Cl. C23C 16/00; B08B 5/00

(52) U.S. Cl. 118/723 R; 134/30

(57) ABSTRACT

A substrate treating apparatus and related cleaning method are disclosed. The apparatus includes a stage heater disposed in the reaction chamber, serving as a first electrode during the generation of in-situ plasma, and supporting a substrate, a shower head disposed in the reaction chamber opposing the stage heater, serving as a second electrode during the generation of the in-situ plasma, and supplying a reaction gas into the reaction chamber, a remote plasma generator disposed external to the reaction chamber and configured to supply a cleaning gas to the reaction chamber following activation of the cleaning gas, and a gas transmitter disposed between the reaction chamber and the remote plasma generator and configured to transmit the reaction gas and the cleaning gas to the shower head.

### CROSS-REFERENCE TO RELATED APPLICATIONS

This patent application claims priority under 35 U.S.C § 119 to Korean Patent Application 2006-78371 filed on Aug. 18, 2006, the subject matter of which is hereby incorporated by reference.

### BACKGROUND OF THE INVENTION

1. Field of the Invention

The present invention relates to substrate treatment apparatuses. More specifically, the invention relates to apparatuses for treating semiconductor substrates and related methods for cleaning such apparatuses.

2. Discussion of Related Art

The fabrication of contemporary semiconductor devices involves the application of a complex sequence of processes to a substrate upon which electrical circuits and related components are formed. Many of these processes are applied in highly specialized apparatuses generically referred to as process chambers. Certain process chambers are used to deposit material layers on a substrate, selectively remove previously deposited material layer, etc.

Many of the processes leave by-products and other unwanted materials on the inner walls of the process chamber. Such by-product accumulations must be removed from the chamber by one or more cleaning processes in order to reduce the risk of substrate contamination.

Consider, for example, a case wherein fabrication of an integrated circuit on a substrate requires the formation of a material layer that functions as a diffusion barrier layer. This is a common task, and materials such as titanium (Ti) or titanium nitride (TiN) have been used as barrier layers. The deposition of the Ti or TiN can be readily accomplished using conventional Chemical Vapor Deposition (CVD) processes.

Unfortunately, the resilient properties that make Ti and TiN excellent barrier layers also make their removal from the inner walls of a process chamber very difficult. However, if such materials are left to accumulate on the inner wall of a process chamber they flake off during subsequent processes and become contamination particles to a subsequently processed substrate. Accordingly, there is a requirement for complete removal of accumulated materials from the inner walls of a process chamber without damaging the sometimes delicate components within the process chamber. Ideally, the use of a cleaning gas would accomplish these mutual purposes.

### SUMMARY OF THE INVENTION

Embodiments of the invention provide a substrate treatment apparatus and related cleaning methods that allow the complete removal of accumulated by-product materials from the apparatus.

In one embodiment, the invention provides a substrate treatment apparatus comprising; a reaction chamber, a stage heater disposed in the reaction chamber, serving as a first electrode during the generation of in-situ plasma, and supporting a substrate, a shower head disposed in the reaction chamber opposing the stage heater, serving as a second electrode during the generation of the in-situ plasma, and supplying a reaction gas into the reaction chamber, a remote plasma generator disposed external to the reaction chamber and configured to supply a cleaning gas to the reaction chamber following activation of the cleaning gas, and a gas transmitter disposed between the reaction chamber and the remote plasma generator and configured to transmit the reaction gas and the cleaning gas to the shower head.

In another embodiment, the invention provides a cleaning method for a substrate treatment apparatus, comprising; generating remote plasma using a cleaning gas, wherein the remote plasma includes activated fluorine radicals, supplying the remote plasma to a reaction chamber and simultaneously generating in-situ plasma in the reaction chamber.

In another embodiment, the invention provides a cleaning method for a substrate treatment apparatus, comprising; supplying a plasma ignition gas to a remote plasma generator, supplying the plasma ignition gas to a reaction chamber, plasmatically discharging the remote plasma generator, supplying a cleaning gas to the remote plasma generator, activating the cleaning gas to generate a radical, supplying the radical to the reaction chamber and simultaneously plasmatically discharging the reaction chamber, and reacting the radical to remove materials accumulated in the reaction chamber.

In another embodiment, the invention provides a cleaning method of a substrate treatment apparatus, comprising; reducing the temperature of a reaction chamber from a deposition process temperature to a cleaning treatment temperature, simultaneously applying remote plasma and in-situ plasma to the reaction chamber at the cleaning treatment temperature, and thereafter, increasing the temperature of the reaction chamber from the cleaning treatment temperature to the deposition process temperature, and performing a preliminary test associated with the deposition process at the deposition process temperature.

### BRIEF DESCRIPTION OF THE DRAWINGS

Figure (FIG.) 1 is a cross-sectional view of a substrate treatment apparatus according to an embodiment of the invention.

FIG. 2 is a graph comparatively illustrating exemplary time and temperature conditions associated with the introduction of gas components in a conventional cleaning method and a cleaning method according to an embodiment of the invention.

FIG. 3 is a flowchart summarizing a cleaning method for a substrate treatment apparatus according to an embodiment of the invention.

### DESCRIPTION OF EMBODIMENTS

The present invention will now be described in some additional detail with reference to the accompanying drawings. This invention may, however, be embodied in many different forms and should not be construed as being limited to only the illustrated embodiments. Rather, these embodiments are presented as teaching examples. Throughout the drawings and written description like numbers refer to like or similar elements.

FIG. 1 is a cross-sectional view of a substrate treatment apparatus 100 according to an embodiment of the invention. Substrate treatment apparatus 100 includes a process (or reaction) chamber 110. The reaction chamber 110 comprises an inner space 114 surrounded by a chamber body 113 comprising a lower part of reaction chamber 110 and chamber lid 111.

An exhaust line 160 is provided to exhaust reaction byproducts and other gases from reaction chamber 110. A valve 162 is positioned on exhaust line 160 between reaction chamber 110 and a vacuum pump 164. Vacuum pump 164 and valve 162 may be operated in combination to define a desired pressure within inner space 114.

A substrate W is loaded on a stage heater 170 disposed proximate a floor surface 114C of inner space 114. Stage heater 170 is adapted to heat substrate W to a predetermined temperature. To accomplish this in one embodiment, stage heater 170 may be electrically connected to a temperature controller 171. Stage heater 170 may also be grounded (or otherwise electrically biased) to form a bottom electrode during processes requiring the generation of plasma. In addition to directly heating wafer W, the temperature of inner space 114 may be controlled by operation of stage heater 170.

A shower head 130 is disposed through chamber lid 111 to extend into inner space 114 in a position opposing stage heater 170. Shower head 130 may be used in various processes to introduce one or more reaction gas(es) into reaction chamber 110. In the illustrated example, shower head 130 is electrically connected to a high-frequency (HF) power supply 136 in order to serve as a top electrode during processes requiring generation of a plasma.

One or more heater(s) 115 are disposed on an outer surface 111A of chamber lid 111. Heater(s) 115 may cooperate with stage heater 170 to define a desired temperature within reaction chamber 110 and more particularly a desired temperature in relation to shower head 130. A temperature controller 116 may be electrically connected to heater(s) 115, to regulate the temperature of shower head 130.

One or more additional heater(s) 117 may be disposed on the outer lateral side surfaces 113B of reaction chamber 110. One or more additional heater(s) 119 may also be disposed on the outer bottom surface 113A of reaction chamber 110. Heater(s) 117 may be electrically connected to a temperature controller 118, and heater(s) 119 may be electrically connected to another temperature controller 120. The foregoing heating elements may be operated in combination to define and maintain a desired temperature within inner space 114.

In the illustrated example, shower head 130 is a multi-layer structure including a top shower head 132 and a bottom shower head 134. Top shower head 132 and bottom shower head 134 are configured to define spaces (e.g., 132A and 134A) into which a reaction gas may be introduced.

In one example, TiCl4 gas is introduced into space 132A and NH3 gas is separately introduced into space 134A. This type of gas introduction into shower head 130 allows the TiCl4 gas and the NH3 gas to remain unmixed until their introduction into inner space 114. In this manner, the potential generation of contamination particles due to pre-mixing of the TiCl4 gas with the NH3 gas prior to introduction into inner space 114 may be suppressed. In the illustrated example, the TiCl4 gas may be introduced into space 132A through an upper injection hole 133, and the NH3 gas may be introduced into space 134A through a lower injection hole 135. The resulting chemical reaction that occurs in inner space 114 will deposit a TiN thin film on substrate W. The chemical reaction caused by the exemplary chemical vapor deposition (CVD) reaction is facilitated by thermal energy provided by one or more of the heater elements or by RF energy provided by a generated plasma.

A gas transmitter 150 is provided outside reaction chamber 110 and controls transportation of various reaction gases to shower head 130. Lines 152, 154, 156 and 158 may be used in combination with gas transmitter 150. For example, a thin film source gas may be introduced via line 154, and a reducing gas or a reaction gas may be introduced via line 152, or vice verse. Respective valves 152A and 154A may be operated to control the flow of gas through lines 152 and 154.

In the working example Introduced above, TiCl4 may be adopted as thin film source gas, H2 as a reducing gas, and N2 or NH3 as a reaction gas. The TiCl4 has may be introduced to gas transmitter 150 via lines 154 and 156, and subsequently supplied to inner space 114 through upper injection hole 133 and space 132A. The H2, N2 and/or NH3 gas may be introduced to gas transmitter 150 via lines 152 and 158, and subsequently supplied to inner space 114 through lower injection hole 135 and space 134A. In one embodiment, lines 152 and 154 are made of aluminum (Al) or an Al-alloy to suppress possible erosion caused by Cl2 gas within the TiCl4 gas.

The gases supplied into inner space 114 of reaction chamber 110 may be excited to a plasma state by the application of high-frequency power provided by high-frequency power supply 136 in order to facilitate the desired chemical reaction. Alternatively, the gases supplied to inner space 114 of reaction chamber 110 may be reacted by the application of thermal energy using stage heater 170, and/or one or more of heaters 115, 117, and 119.

In the working example, the resulting chemical reaction (or reduction) causes a Ti or TiN thin film to be deposited on substrate W. However, the Ti or TiN thin film is also deposited on the components forming shower head 130, as well as stage heater 170, and inner walls 114A, 114B, and 114C of reaction chamber 110.

A remote plasma generator 140 may be externally configured for operation with reaction chamber 110. One or more cleaning gas(es) may be introduced to remote plasma generator 140 via line 144 and high frequency energy applied to remote plasma generator 140 from a high-frequency power supply 146 in order to generate a plasma. High-frequency power supply 146 may be operated independently of high-frequency power supply 136. The plasma generated from remote plasma generator 140 may be supplied through line 142, flow control valve 142A, gas transmitter 150, spaces 132A and/or 134A, and lines 156 and 158. The plasma supplied to spaces 132A and 134A is subsequently supplied to inner space 114 of reaction chamber 110 through injection holes 133 and 135.

Conventionally, halide gas such as F2, ClF3, Cl2, and NF3 is used as a cleaning gas. It is well known that the reactivity of halide gas to metals is F2>ClF3>Cl2>NF3. However, Cl2 has a relatively low reactivity during substrate cleaning. Therefore, Cl2 is not preferred as a cleaning gas.

In contrast, ClF3 has a relatively higher reactivity as a cleaning gas over Cl2 and other halide gases, and a relatively better cleaning efficiency may be obtained even when a cleaning treatment is conducted following a deposition process applied to approximately 500 to 1,000 substrates. However, the relatively higher reactivity of ClF3 may actually damage some of the components forming shower head 130 or stage heater 170. For example, where TiCl4 gas is used in a CVD process, stage heater 170 may apply a temperature ranging from 650 to 700° C. Under these temperature conditions, the Cl2 gas originating from ClF2 will react with aluminum nitride (AlN) components of stage heater 170 to generate AlxFy or AlxCly. That is, stage heater 170 is etched by the ClF3 cleaning gas. Such etching may also occur where shower head 130 is formed from aluminum or aluminum nitride.

For this reason, a cleaning process using ClF3 should be conducted only after the ambient temperature of reaction chamber 110 and its constituent components fall to a range of approximately 250 to 300° C. in order to prevent damage to stage heater 170 or shower head 130 under the foregoing assumptions. In practical effect, this means that a cleaning process using ClF3 may not be applied to reaction chamber 110 for approximately three hours in order to allow cooling of reaction chamber 110 from the 650 to 700° C. range down to the 250 to 300° C. range. As a result of the foregoing etching problem or the extended cooling delay to avoid same, the use of ClF3 gas is not preferred as cleaning gas.

In view of the foregoing and as will be described in some additional detail hereafter, Cl2-free F2 or NF3 gases are suitable cleaning gas(es). Especially since the reactivity of NF3 is lower than that of other halide gases, components within reaction chamber 110 are unlikely to be damaged during cleaning. Moreover, although stage heater 170, shower head 130, and other components of reaction chamber 110 are made of aluminum or aluminum nitride, they are not etched because Cl2 has been excluded from the cleaning reaction.

In the context of the exemplary reaction chamber 110 illustrated in FIG. 1, a cleaning process using NF3 may be applied that uses a remote plasma and in-situ plasma simultaneously. (In this context, the term “simultaneously” means the overlapping application of the remote plasma and in-situ plasma to any degree). Specifically, plasma including fluorine radicals generated by remote plasma generator 140 is supplied to reaction chamber 110 and a high-frequency power from high-frequency power supply 136 is applied to shower head 130 to generate in-situ plasma between shower head 130 and stage heater 170. Accordingly, inner space 114 of reaction chamber 110 is filled with fully activated fluorine radicals. Thus, a gaseous TiF4 is generated by the reaction of Ti or TiN accumulated in inner space 114 to the fluorine radicals to exhibit superior etching efficiency. Moreover, stage heater 170 is protected from possible etching damage even when the ambient temperature surrounding stage heater 170 is in the range of 350 to 450° C.

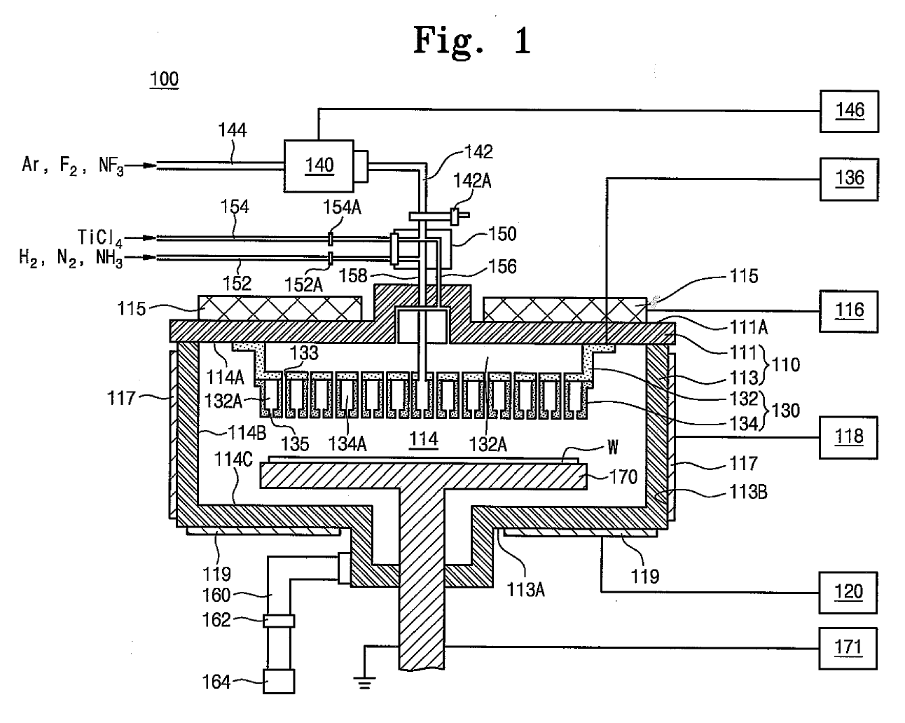

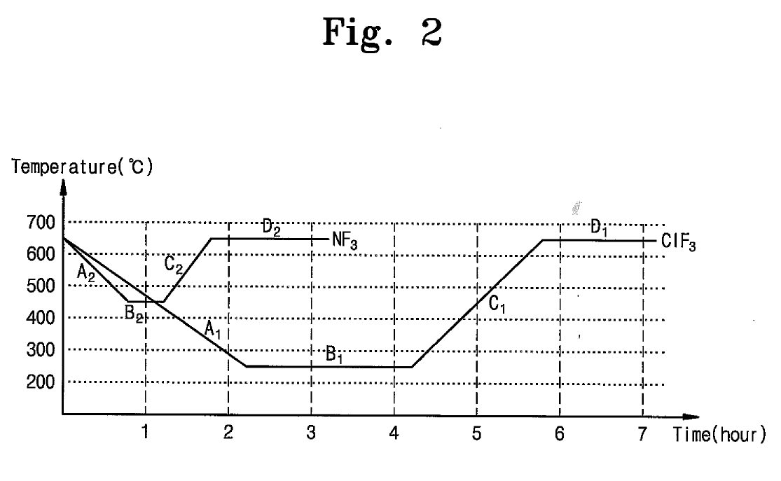

FIG. 2 is a graph comparatively illustrating reaction chamber temperatures and timing requirements for a conventional cleaning method using ClF3 as a cleaning gas, and a cleaning method according to an embodiment of the invention using NF3 as a cleaning gas. Referring to FIG. 2, the conventional cleaning method requires waiting until the reaction chamber temperature drops (period A1). Then cleaning may be performed (period B1). After the reaction chamber is cleaned, its temperature must again be raised to the desired reaction temperature (e.g., around 650° C.) (period C1). Then, the CVD process may again be performed in the reaction chamber after the required environment has been established (period D1).

In certain practical examples, period A1 may last approximately 2 hours 20 minutes in order to drop the temperature of the reaction chamber from approximately 600 to 700° C., assuming the working example of a CVD process using TiCl4, to a temperature of approximately 200 to 300° C. in order to avoid etching damage to stage heater 170. Period B1 may take approximately 2 hours to perform a cleaning process at a temperature of approximately 250° C. Period C1 may take approximately 1 hour and 10 minutes to raise the temperature of the reaction chamber from 250° C. to approximately 650° C. in order to again perform a TiCl4 CVD process. Period D1 may take approximately 1 hour and 20 minutes to re-establish an environment within the reaction chamber suitable to again perform the TiCl4 CVD once the temperature of reaction chamber 110 is raised to approximately 650° C. Consequently, in one practical example, it takes at least 7 hours (including a cleaning time of 2 hours) to cycle a reaction chamber through cleaning process using ClF3. Of note, in a case where Cl2 is used as the cleaning gas, a similar time plot is obtained.

In contrast, a cleaning method according to an embodiment of the invention also includes reducing the temperature in the reaction chamber (period A2), cleaning the reaction chamber (period B2), raising the temperature within the reaction chamber (period C2), and again establishing a required environment within the reaction chamber 110 (period D2).

However, period A2 involves a much smaller temperature drop, i.e., from approximately 600 to 700° C. to approximately 350 to 450° C. so that stage heater 170 is not etched by the NF3 cleaning gas. Thus, time required for temperature reduction within reaction chamber 110 is much shorter than the time required for the conventional example (e.g., period A1).

Further, during period B2, if NF3 including fluorine radicals activated by plasma generated from an external plasma generator are supplied to the reaction chamber and, at the same time, plasma is generated in-situ in the reaction chamber, the generation of the fluorine radicals is maximized to enhance cleaning efficiency. Thus, cleaning period B2 is markedly shorter than conventional cleaning period B1.

The period C2 required to return the reaction chamber to a desired temperature is also shorter than conventional period C1, as the required temperature rise is about half that of the conventional example

The environmental re-establishment period D2 is, however, nearly equal to the time D1 required by the conventional approach. This is not surprising since aspects of the invention are not directed to process re-establishment improvements. In sum, the illustrated working example of the present invention is about 4 hours shorter than the conventional example (i.e., about 3 hours instead of about 7 hours). Of note, in a case where F2 is used as a cleaning gas, a similar time plot is obtained.

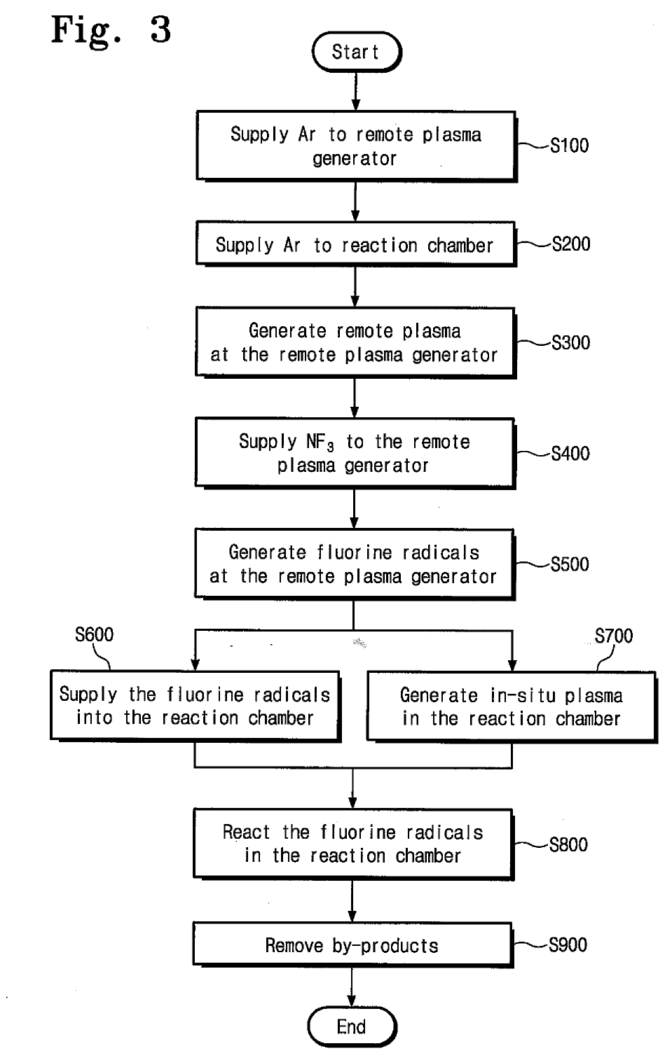

FIG. 3 is a flowchart summarizing a cleaning method for a reaction chamber as an example of a substrate treatment apparatus according to an embodiment of the invention. Referring to FIG. 3 and FIG. 1, the working example will be continued in the context of a Ti or TiN thin film being deposited on a substrate loaded in reaction chamber 110 followed by removal of the substrate and cleaning of the reaction chamber. The cleaning process may be performed in this context following deposition treatment of about 500 to 1,000 substrates.

Thus, it is assumed that the cleaning process requires a reaction chamber temperature drop from approximately 600 to 700° C. to approximately 350 to 450° C. This cleaning temperature range may be established by controlling operation of stage heater 170.

First, argon (Ar) is supplied to a remote plasma generator 140 via line 144 (S100). Argon (Ar) may also be directly supplied to inner space 114 of reaction chamber 110 via lines 142, 156, and 158 (S200). Argon (Ar) may be supplied during or after reduction of the temperature in reaction chamber 110. Since the argon (Ar) is introduced to ignite a plasma, other gases suitable to plasma ignition (e.g., other inert gases) may be used in conjunction with or as an alternative to the argon (Ar).

A high-frequency power generated by high-frequency power supply 146 is applied to remote plasma generator 140 to generate plasma (S300). Then, NF3 as a cleaning gas is supplied to remote plasma generator 140 via line 144 to be activated (S400). Thus, fluorine radicals are generated at the remote plasmas generator 140 (S500).

The activated NF3 including the fluorine radicals generated at remote plasma generator 140 (hereinafter referred to “remote plasma”) is supplied to reaction chamber 110 (S600). Before passing into reaction chamber 110, the remote plasma is supplied to spaces 132A and 134A of shower head 130 via lines 156 and 158. The remote plasma supplied to spaces 132A and 134A is then supplied to inner space 114 through injection holes 133 and 135, so that shower head 130 is cleaned by the reaction of the fluorine radicals.

Simultaneously with the supply of the remote plasma to reaction chamber 110, high-frequency power is supplied to shower head 130 by driving high-frequency power supply 136 to generate plasma in-situ in reaction chamber 110 (S700). The generation of the in-situ plasma in reaction chamber 110 may be done before or after supplying the remote plasma to reaction chamber 110. The supply of the remote plasma to reaction chamber 110 as well as generation of the in-situ plasma in reaction chamber 110 enables generation of the fluorine radicals.

The reaction of the fluorine radicals in reaction chamber 110 may be understood in relation to equations 5 or 6 below.

Ti(s)+NF3(g)→TiF4(g)+N2(g) (Equation 5)

TiN(s)+NF3(g)→TiF4(g)+N2(g) (Equation 6)

As shown in equations 5 or 6, Ti or TiN is gasified by reaction of the fluorine radicals within reaction chamber 110. During this reaction, reaction chamber 110 is maintained at a relatively lower pressure state by operation of vacuum pump 164.

In one more specific embodiment of the invention, conditions adapted to the performance of a cleaning process using activated NF3 are set forth in Table 1 below.

TABLE 1

| | | | | Pressure | | |
|---|---|---|---|---|---|---|
| | Supply | Supply | | of | Temperature | |
| | Amount of | Amount | Plasma | Reaction | of Reaction | Cleaning |
| | NF3 | of Ar | Power | chamber | chamber | Time |
| Spec | 100-1,000 sccm | 100-1,000 sccm | 10 kW, | 0.5-5 Torr | 350-450° C. | 20 min |
| | | | 400 kHz | | | |

sccm = standard cubic centimeters per minute

As described above, the cleaning process using NF3 is effective in removing Ti or TiN accumulated on stage heater 170, shower head 130, and other exposed parts of inner space 114 of reaction chamber 110 (e.g., inner walls 114A, 114B, and 114C). Byproducts from the foregoing exemplary CVD process, such as NH4Cl, TiNxCly, TICl4nNH3 and the like, may also be removed (S900).

In the working example, the temperature of reaction chamber 110 is raised to about 650° C. for a TiCl4 CVD process. Additionally, establishment of an environment within reaction chamber 110 to perform this CVD process may include prior to the Ti or TiN deposition, a preliminary deposition process designed to test whether the deposition process is safe. For example, a dummy substrate may be placed in reaction chamber 110 and a Ti or TiN deposition process performed. The results may be used to confirm whether the thickness or resistance of a deposited layer is acceptable.

As illustrated by the comparative examples of FIG. 2, it takes approximately 3 hours to reduce the temperature of reaction chamber 110, react fluorine radicals, raise the temperature of reaction chamber 110, and establish a desired environment in reaction chamber 110. This overall processing time is much shorter than the conventional example. Further, practical cleaning time required for reaction of the fluorine radicals is also much shorter than in the conventional cleaning method. Moreover, remote plasma and in-situ plasma are simultaneously supplied to enhance a cleaning efficiency.

While the foregoing examples have been drawn to a process for depositing Ti or TiN using reaction chamber 110, it will be understood that the cleaning using NF3 is not limited only to such processes. For example, a cleaning method according to an embodiment of the invention may be applied to a reaction chamber following deposition of WSi or metal layers, and insulation layers such as SiO2, SiON, SiC or SiOC.

Although the present invention has been described in connection with certain embodiments of the invention illustrated in the accompanying drawings, it is not limited thereto. It will be apparent to those skilled in the art that various substitutions, modifications and changes may be made without departing from the scope of the invention as defined by the attached claims.

What is claimed is:

1. A substrate treatment apparatus comprising:
a reaction chamber;
a stage heater disposed in the reaction chamber, serving as a first electrode during the generation of in-situ plasma, and supporting a substrate;
a shower head disposed in the reaction chamber opposing the stage heater, serving as a second electrode during the generation of the in-situ plasma, and supplying a reaction gas into the reaction chamber;
a remote plasma generator disposed external to the reaction chamber and configured to supply a cleaning gas to the reaction chamber following activation of the cleaning gas; and
a gas transmitter disposed between the reaction chamber and the remote plasma generator and configured to transmit the reaction gas and the cleaning gas to the shower head.

2. The substrate treatment apparatus of claim 1, wherein the gas transmitter comprises a first line supplying the reaction gas, a second line supplying the cleaning gas from the remote plasma generator, and a third line supplying the reaction gas and cleaning gas to the shower head.

3. The substrate treatment apparatus of claim 2, wherein the reaction gas includes a first gas and a second gas;
the first line includes lines separately supplying the first and second gases; and
the third line includes lines separately supplying the first and second gases to the shower head.

4. The substrate treatment apparatus of claim 3, wherein the shower head comprises a first space receiving the first gas and a second space receiving the second gas.

5. The substrate treatment apparatus of claim 4, wherein the shower head comprises:
an upper injection hole through which the first gas supplied to the first space is supplied to the reaction chamber; and
a lower injection hole through which the second gas supplied to the second space is supplied to the reaction chamber.

6. The substrate treatment apparatus of claim 5, wherein the cleaning gas is supplied to the reaction chamber via the upper and lower injection holes after being supplied to the first and second spaces.

7. The substrate treatment apparatus of claim 1, further comprising:
a first high-frequency (HF) power supply applying HF power to the remote plasma generator; and
a second HF power supply applying HF power to the shower head, wherein the second HF power supply operates independent of the first HF power supply.

8. The substrate treatment apparatus of claim 1, further comprising:
a heater configured to apply thermal energy to the shower head.

9. The substrate treatment apparatus of claim 8, further comprising:
a heater configured to apply thermal energy to the reaction chamber.

10. The substrate treatment apparatus of claim 1, further comprising:
a vacuum pump exhausting the reaction chamber through an exhaust line.

11. The substrate treatment apparatus of claim 1, wherein the cleaning gas comprises fluorine (F2) or nitrogen trifluoride (NF3).

12. A cleaning method for a substrate treatment apparatus, comprising:
generating remote plasma using a cleaning gas, wherein the remote plasma includes activated fluorine radicals;
supplying the remote plasma to a reaction chamber and simultaneously generating in-situ plasma in the reaction chamber.

13. The cleaning method of claim 12, wherein generating remote plasma comprises:
supplying a first gas to a remote plasma generator;
discharging the remote plasma generator;
supplying a second gas to the remote plasma generator; and
activating the second gas to generate the fluorine radicals.

14. The cleaning method of claim 13, wherein generating in-situ plasma in the reaction chamber comprises:
supplying the first gas to the reaction chamber; and
discharging the reaction chamber.

15. The cleaning method of claim 14, wherein the first gas includes a plasma ignition gas, and the second gas includes the cleaning gas.

16. The cleaning method of claim 15, wherein the cleaning gas includes a chlorine-free halide gas.

17. The cleaning method of claim 16, wherein the cleaning gas comprises fluorine (F2) or nitrogen trifluoride (NF3).

18. The cleaning method of claim 17, wherein the plasma ignition gas includes argon (Ar).

19. A cleaning method for a substrate treatment apparatus, comprising:
supplying a plasma ignition gas to a remote plasma generator;
supplying the plasma ignition gas to a reaction chamber;
plasmatically discharging the remote plasma generator;
supplying a cleaning gas to the remote plasma generator;
activating the cleaning gas to generate a radical;
supplying the radical to the reaction chamber and simultaneously plasmatically discharging the reaction chamber; and
reacting the radical to remove materials accumulated in the reaction chamber.

20. The cleaning method of claim 19, wherein the plasma ignition gas includes argon (Ar), and the cleaning gas includes fluorine (F2) or nitrogen trifluoride (NF3).

21. The cleaning method of claim 19, wherein the radical includes a fluorine radical.

22. A cleaning method of a substrate treatment apparatus, comprising:
reducing the temperature of a reaction chamber from a deposition process temperature to a cleaning treatment temperature;
simultaneously applying remote plasma and in-situ plasma to the reaction chamber at the cleaning treatment temperature; and thereafter,
increasing the temperature of the reaction chamber from the cleaning treatment temperature to the deposition process temperature; and
performing a preliminary test associated with the deposition process at the deposition process temperature.

23. The cleaning method of claim 22, wherein simultaneously applying remote plasma and in-situ plasma to the reaction chamber at the cleaning treatment temperature comprises:
supplying a plasma ignition gas to a remote plasma generator external to the reaction chamber;
supplying the plasma ignition gas to the reaction chamber;
discharging the remote plasma generator to generate remote plasma;
activating a cleaning gas in the remote plasma generator; and
supplying the activated cleaning gas to the reaction chamber and simultaneously discharging the reaction chamber to generate in-situ plasma.

24. The cleaning method of claim 23, wherein the plasma ignition gas includes argon (Ar), and the cleaning gas includes fluorine (F2) or nitrogen trifluoride (NF3).
